(19) United States
(12) Patent Application Publication
(10) Pub. No.: US 2024/0210470 A1
(43) Pub. Date: Jun. 27, 2024

(54) SCAN CHAIN DIAGNOSTIC ACCURACY USING HIGH VOLUME MANUFACTURING FUNCTIONAL TESTING

(71) Applicant: Intel Corporation, Santa Clara, CA (US)

(72) Inventors: Nir BONE, Afula (IL); David TURJEMAN, Zikhron Ya'akov (IL); Hussein DEEB, Judaida Macker (IL)

(21) Appl. No.: 18/089,546

(22) Filed: Dec. 27, 2022

(51) Int. Cl. G01R 31/3177; G06F 30/333

(52) U.S. Cl. CPC G01R 31/3177; G06F 30/333

(57) ABSTRACT

This disclosure describes systems, methods, and devices related to diagnose a broken scan chain and isolate the broken cell. A device may perform a functional test on a plurality of central processing unit (CPU) cells in a chain. The device may propagate data through a combinatoric logic. The device may capture results in sequential flip-flops associated with scan. The device may utilize the results in a next combinatoric logic. The device may utilize shifted-out data to isolate a first broken cell based on the functional test.

### TECHNICAL FIELD

The present disclosure is generally related to the field of process yield debugging. More particularly, improving the diagnosis resolution of a broken scan chain by using high volume manufacturing (HVM) functional testing.

### BACKGROUND

SCAN-based testing is a common high-volume manufacturing (HVM) design-for-test (DFT). Sequential flops are connected in serial as a SCAN chain, as a result, a large amount of the failing die can be due to process defects that cause a broken SCAN chain. Therefore, SCAN chain diagnosis is important to improve process yield.

### BRIEF DESCRIPTION OF THE DRAWINGS

FIGS. 1A-1D depict illustrative schematic diagrams for a SCAN implementation.

FIG. 2 depicts the implementation of SCAN D-mux cells in a typical logic design.

FIG. 3 depicts the implementation of SCAN infrastructure.

FIG. 4 depicts an illustrative schematic diagram for scan chain diagnostic, in accordance with one or more example embodiments of the present disclosure.

FIG. 5 depicts an illustrative schematic diagram for scan chain diagnostic, in accordance with one or more example embodiments of the present disclosure.

FIG. 6 illustrates a flow diagram of a process for an illustrative scan chain diagnostic system, in accordance with one or more example embodiments of the present disclosure.

Certain implementations will now be described more fully below with reference to the accompanying drawings, in which various implementations and/or aspects are shown. However, various aspects may be implemented in many different forms and should not be construed as limited to the implementations set forth herein; rather, these implementations are provided so that this disclosure will be thorough and complete, and will fully convey the scope of the disclosure to those skilled in the art. Like numbers in the figures refer to like elements throughout. Hence, if a feature is used across several drawings, the number used to identify the feature in the drawing where the feature first appeared will be used in later drawings.

### DETAILED DESCRIPTION

The following description and the drawings sufficiently illustrate specific embodiments to enable those skilled in the art to practice them. Other embodiments may incorporate structural, logical, electrical, process, algorithm, and other changes. Portions and features of some embodiments may be included in, or substituted for, those of other embodiments. Embodiments set forth in the claims encompass all available equivalents of those claims.

As logic devices become more complex, it took increasing amounts of time and effort to manually create and validate tests, it was too hard to determine test coverage, and the tests took too long to run. The technique is referred to as a functional test. So the industry moved to a design for test (DFT) approach where the design was modified to make it easier to test. The approach that ended up dominating the integrated circuit (IC) test is called structural, or “SCAN, (or scan)” test because it involves scanning test patterns into internal circuits within the device under test (DUT). The design's flip-flops are modified to allow them to function as stimulus and observation points, or “scan cells” during the test while performing their intended functional role during normal operation.

As part of the implementation, the entire sequential flops are connected in serial as a SCAN chain, as a result, a large amount of the failing die was due to process defects which cause a broken SCAN chain. Therefore, SCAN chain diagnosis is crucial to improve process yield.

Previously proposed methods for SCAN chain diagnosis and the existing methods used in the industry are not achieving good statistics for “one-cell” resolution and as a result, the physical failure isolation is complex and not always succeeded to isolate the defect.

The current industry diagnosis tools use automatic SCAN test pattern generation (ATPG) patterns which are applied to identify the range of suspected SCAN Chain cells by using software tools. The idea is to use the SCAN ATPG test to inject value into the chain and read (shift out) the results. The shifted-out data use as input to the diagnosis tool which is targeted to isolate the broken cell. The success rate of these tools is typically poor and not sufficient. There are methods to get “one-cell” resolution, but they use hardware and therefore require extra area in SCAN chains and/or SCAN cells, which are not applicable in production design because of the cost/area/power impact.

Example embodiments of the present disclosure relate to systems, methods, and devices for improving scan chain diagnostic accuracy using high volume manufacturing (HVM) functional testing.

In one or more embodiments, a scan chain diagnostic system may facilitate the use of existing high volume manufacturing (HVM) functional testing content to enable to run chain diagnosis before the wafer fabricate to assemble the unit. Once a broken cell is found, physical failure analysis (PFA) may be done to find the process defect to improve the process yield.

In one or more embodiments, a scan chain diagnostic system may improve diagnosis resolution by using existing HVM functional content in wafer level and/or die-package level and without hardware changes.

The above descriptions are for purposes of illustration and are not meant to be limiting. Numerous other examples, configurations, processes, algorithms, etc., may exist, some of which are described in greater detail below. Example embodiments will now be described with reference to the accompanying figures.

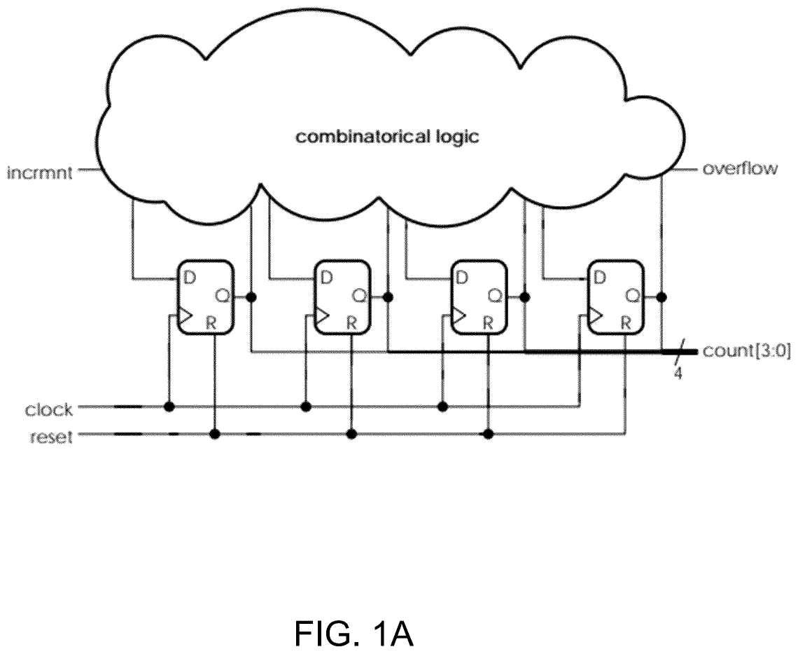

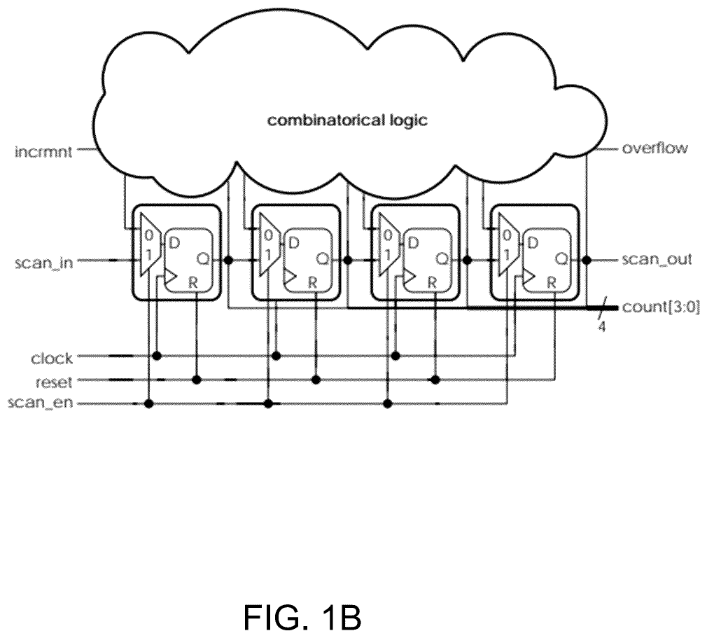

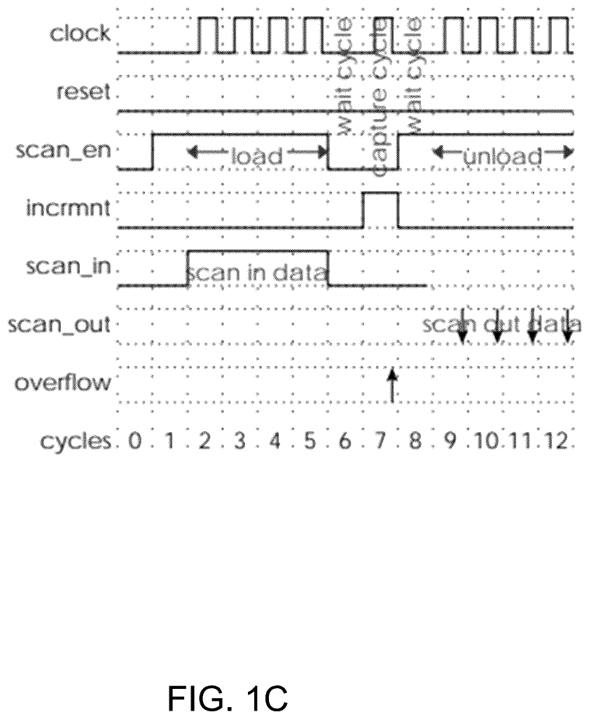

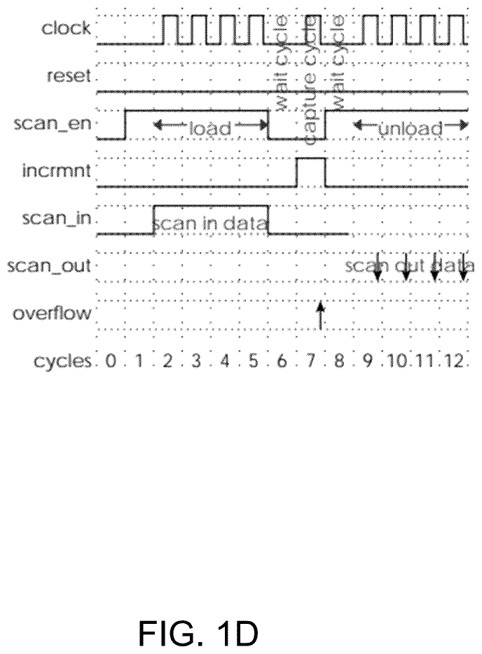

FIGS. 1A-1D depict illustrative schematic diagrams for a SCAN implementation.

For any modern chip design with a considerably large portion of logic, design for test (DFT) and implementing scan test are mandatory parts of the design process that helps to reduce the complexity of testing sequential circuits. The basic concept of a scan test is to connect memory elements like flip-flops or latches forming chains so that shifting through scan chains allows to control and observe the states of the DUT. Since scan vectors are based on regular and uniform structures, basic knowledge about scan designs, scan test modes, and targeted fault models helps to interpret scan vectors. Therefore, in this paper a basic introduction to scan test is given, so that a test engineer who debugs scan test can be more efficient in a first level of fault analysis—beyond just being able to do logging of failing pins and cycles.

Scan patterns are widely used to efficiently test the logic of DUT's. While additional functional tests might be necessary to fill some test gaps, a well-prepared scan test allows the detecting of a very high percentage of manufacturing failures, requiring a drastically smaller amount of test data and test time compared to functional tests. To enable a scan test for a chip design, additional test logic must be inserted; this is called “scan insertion”. Scan insertion consists of two steps: 1) replace plain memory cells like flip-flops (FFs) or latches by scan cells; and 2) connect these together forming one or more chains. Scan cells can be operated in two modes, the functional/mission mode used during normal operation and the scan mode that allows shifting through the scan chains.

FIG. 1A shows a small example circuit without scan that implements a 4 bit counter with just three inputs: a clock input “clock”, an input “incrmnt” to increment the counters value and a reset signal “reset” to set the counter back to “0”. The outputs “count” allows to read the counters value. Finally, output “overflow” is a flag which is set if the counter exceeds its counting range.

FIG. 1B shows the same circuit after scan insertion, with scan cells forming a chain with input “scan_in” and output “scan_out”. The input “scan_en” has been added to control the mode of the scan cells. With scan cells supporting functional/mission mode and scan mode, in general scan test works as follows: Shifting into scan chains is used to directly set the state of the DUT, then one or more clock cycles of normal operation is applied, optionally DUT outputs are checked for correct values, and finally the resulting state is shifted out via scan chains and compared to the expected state to check for the correct behaviour of the DUT.

FIG. 1C shows an example of a scan pattern for the 4 bit counter introduced above. When data is shifted into the scan chain, i.e. the scan chain is loaded in scan mode, the required time depends on the size of the longest scan chain and the underlying frequency, called “shift frequency” or “scan frequency”. Typically, scan chains consist of hundreds, or thousands of scan cells and the shift frequency is lower than frequencies used for functional test. In FIG. 1C, the shift cycles for loading the scan chain are four cycles, cycles 2-5, according to the number of scan cells in the design shown in FIG. 1B. The shift cycles can be easily identified because “scan_en” is high and the clock is toggling. After the scan load sequence and optionally additional wait cycles, one or a few clock cycles are applied in functional/mission mode to launch certain events in the DUT and to capture DUT's response. These cycles are often called “launch cycles” and/or “capture cycles” and might run with a different frequency compared to the normal operation of the device. In FIG. 1C cycles 6 and 8 are wait cycles that have been inserted because of the transitions of “scan_en” to low and then back again to high—to give enough time to propagate the transitions to the scan cells. There is only one capture cycle 7 (and no dedicated launch cycle), running with the same clock as for shifting, but the scan cells operate in functional/mission mode (“scan_en” is low). Furthermore, in this cycle the output “overflow” is compared to “high”. Finally, the captured response is shifted out of the scan chains and compared to expected values; this is also called “chain unload”. In FIG. 1C, chain unload is performed in cycles 9-12. The whole sequence of chain load, launch/capture cycles and chain unload is called in the following a scan pattern. Usually, a scan test consists of hundreds or thousands of scan patterns.

While the response data of a scan pattern is shifted out of a scan chain, the scan chain can be simultaneously loaded with the scan input data of the following pattern. This can be any data, so this is the reason, why in FIG. 1C the next scan in data is not shown explicitly. Furthermore, the required test time for a scan test depends mostly on the number of scan patterns, the size of the largest scan chain and the shift frequency, but less on the frequency during launch/capture. The efficiency of a scan test compared to a functional test can be easily explained with the small example of a 4 bit counter given above: Of course, a test for the overflow flag would be mandatory. Using a functional test, this can be done only by resetting the counter and increment the value for 2\hat{ }4=16 clock cycles. On the other side, if a scan test is implemented, for testing the overflow flag it is enough to shift into the scan chain the “1111” pattern and then increment the counter once in normal operation mode and check the overflow flag. Shifting out data can be used to check, if the counters value was correctly set back to “0000”, essentially requiring only 9 cycles.

FIG. 1D shows the corresponding pattern and because of some padding four cycles are added. In cycle 7 the value of the output “overflow” is compared to “high”. Additionally, in this cycle the test could also check if “0000” is the value of the outputs “count[3:0]” (not shown in FIG. 1D). While the difference between 16 clock cycles for a functional test and 9 or 13 clock cycles for scan test is rather small in this case, obviously it will become a huge difference if instead of a 4 bit counter a 64 bit counter has to be tested.

Functional testing is sets machine instructions (or opcode) which loaded into the chip cache and then execute on the CPU. The target is to check the CPU functionality to ensure there are no process defects.

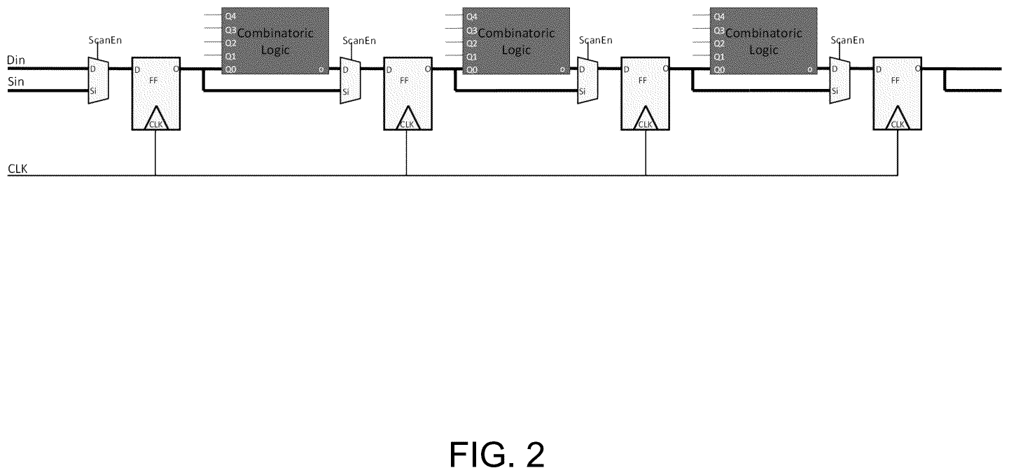

FIG. 2 depicts the implementation of SCAN D-mux cells in typical logic design.

Referring to FIG. 2, there is shown that the SCAN cell is connected in serial as SCAN chain by Si (Serial In) input which is selected by the D-mux in SCAN mod.

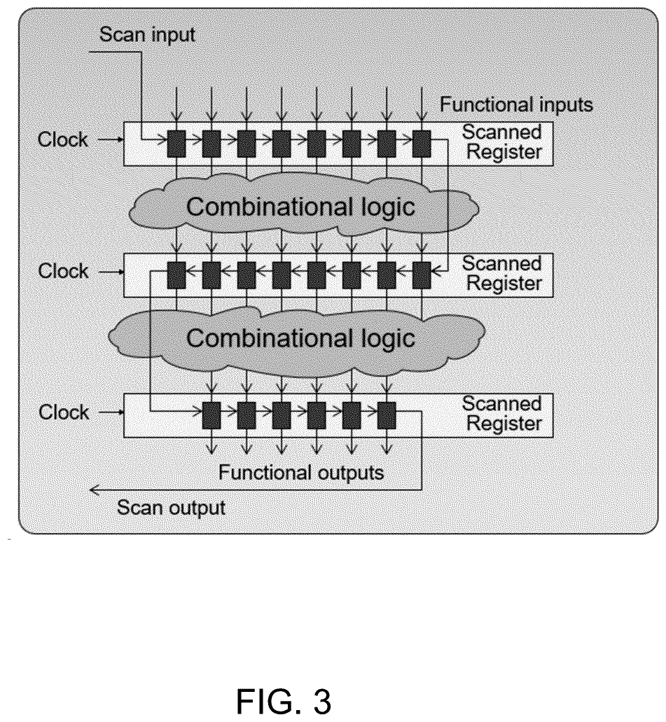

FIG. 3 depicts the implementation of SCAN infrastructure.

Referring to FIG. 3, there is shown the SCAN infrastructure in an existing design, where data can be injected by the SCAN cells into the combinatoric logic and can be read by SCAN cells and shifted out for post-processing. For CT diagnosis we are using the SCAN to read the data, which is the results of the functional test.

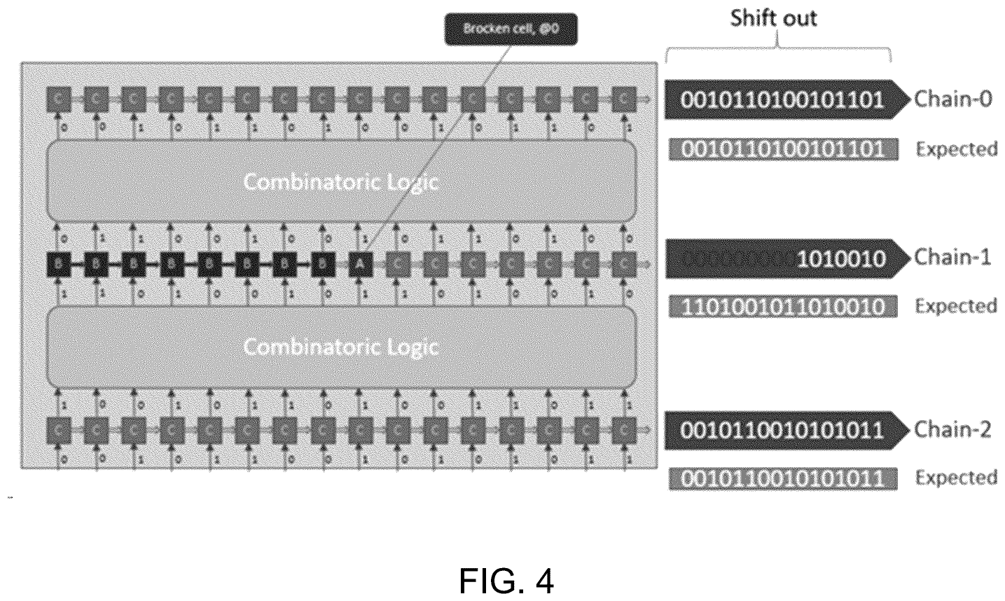

FIG. 4 depicts an illustrative schematic diagram for scan chain diagnostic, in accordance with one or more example embodiments of the present disclosure.

Referring to FIG. 4, there is shown a functional test run and the values that are propagated through the combinatoric logic and captured in scan cells FF and shifted out by the SCAN chain than it analyzes to find the broken cell which is impacted by the stack-at.

In one or more embodiments, a scan chain diagnostic system may facilitate that the functional content may run and propagate values through the combinatoric logic. The results are captured in sequential flip-flops which have SCAN. In FIG. 4, there is shown a stack-at defect in scan-cell “A” which is part of chain-1. When the data is shifted out of the chains, the cells/data (labeled “B”) before cell “A” will be corrupted. The cells/data (labeled “C”) will shift out the correct data. The shifted-out data on chain-0 and chain-2 is correct since the chains are not broken while the data on chain-1 is corrupted. The reference data is taken from a good part, thus, by analyzing the shift-out data, it is possible to find the stack-at scan cell. The stack-at cell is the first mismatch between the shift-out data to the expected data.

It is understood that the above descriptions are for purposes of illustration and are not meant to be limiting.

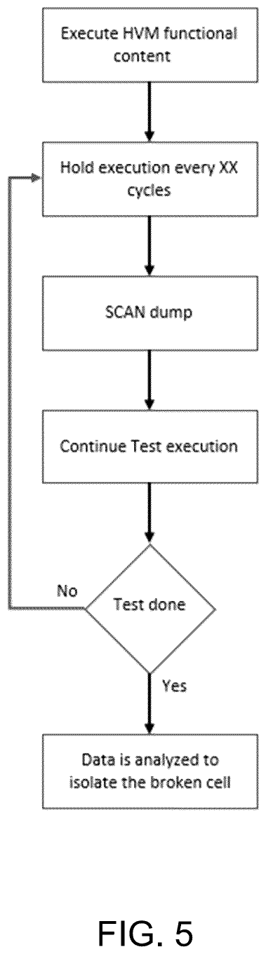

FIG. 5 depicts an illustrative schematic diagram for scan chain diagnostic, in accordance with one or more example embodiments of the present disclosure.

Referring to FIG. 5, there is shown a flow for the shift out of the data while running the functional test.

The flow starts by running a functional test on the CPU. during the execution, the value propagates through the combinatoric logic, is stored in a flip-flop, and used as input to the next combinatoric logic and so on. a scan chain diagnostic system may hold the test execution every XX cycle, the XX is parameter which can be changed based on the implementation. The next step is to shift out (SCAN Dump) the FF data by the serial FF's data which is connected as a chain. After the data shifted out, the execution resume, hold after XX cycle SCAN Dump and so on. When the execution of the functional test done, the shifted-out data may be used to post processing analysis to isolate the broken cell. The general idea is to find from which point (FF) on the chain, the cells that are not toggling. The first cell (from the output side) that did not toggle indicates that it is the broken cell.

It is understood that the above descriptions are for purposes of illustration and are not meant to be limiting.

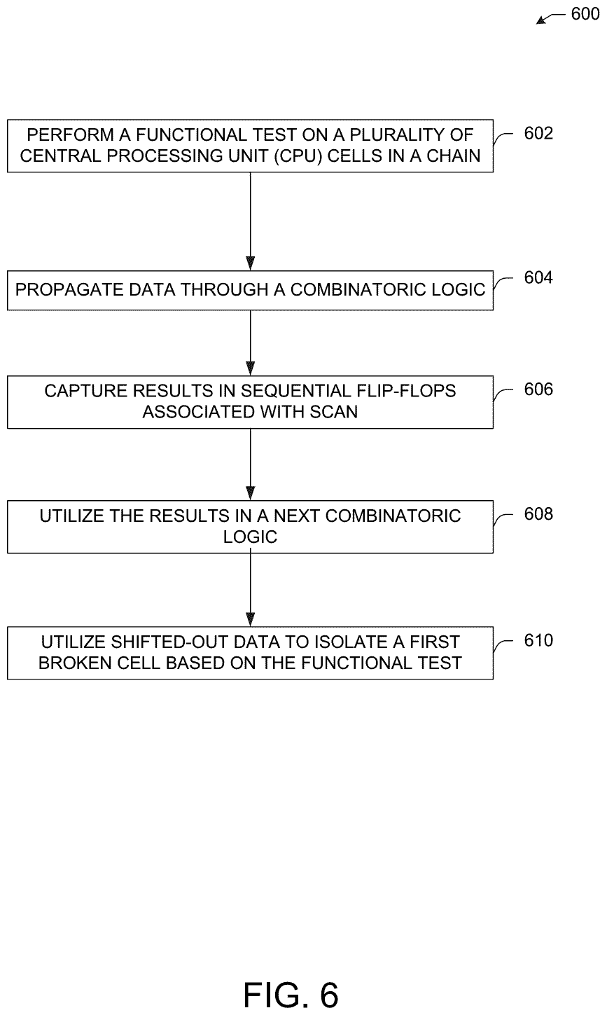

FIG. 6 illustrates a flow diagram of process 600 for a scan chain diagnostic system, in accordance with one or more example embodiments of the present disclosure.

At block 602, a device may perform a functional test on a plurality of central processing unit (CPU) cells in a chain.

At block 604, the device may propagate data through a combinatoric logic.

At block 606, the device may capture results in sequential flip-flops associated with scan.

At block 608, the device may utilize the results in a next combinatoric logic.

At block 610, the device may utilize shifted-out data to isolate a first broken cell based on the functional test.

It is understood that the above descriptions are for purposes of illustration and are not meant to be limiting.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, yet still co-operate or interact with each other.

In addition, in the foregoing Detailed Description, various features are grouped together in a single example to streamline the disclosure. This method of disclosure is not to be interpreted as reflecting an intention that the claimed examples require more features than are expressly recited in each claim. Rather, as the following claims reflect, the inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code to reduce the number of times code must be retrieved from bulk storage during execution. The term “code” covers a broad range of software components and constructs, including applications, drivers, processes, routines, methods, modules, firmware, microcode, and subprograms. Thus, the term “code” may be used to refer to any collection of instructions which, when executed by a processing system, perform a desired operation or operations.

Logic circuitry, devices, and interfaces herein described may perform functions implemented in hardware and implemented with code executed on one or more processors. Logic circuitry refers to the hardware or the hardware and code that implements one or more logical functions. Circuitry is hardware and may refer to one or more circuits. Each circuit may perform a particular function. A circuit of the circuitry may comprise discrete electrical components interconnected with one or more conductors, an integrated circuit, a chip package, a chipset, memory, or the like. Integrated circuits include circuits created on a substrate such as a silicon wafer and may comprise components. And integrated circuits, processor packages, chip packages, and chipsets may comprise one or more processors.

Processors may receive signals such as instructions and/or data at the input(s) and process the signals to generate the at least one output. While executing code, the code changes the physical states and characteristics of transistors that make up a processor pipeline. The physical states of the transistors translate into logical bits of ones and zeros stored in registers within the processor. The processor can transfer the physical states of the transistors into registers and transfer the physical states of the transistors to another storage medium.

A processor may comprise circuits to perform one or more sub-functions implemented to perform the overall function of the processor. One example of a processor is a state machine or an application-specific integrated circuit (ASIC) that includes at least one input and at least one output. A state machine may manipulate the at least one input to generate the at least one output by performing a predetermined series of serial and/or parallel manipulations or transformations on the at least one input.

The logic as described above may be part of the design for an integrated circuit chip. The chip design is created in a graphical computer programming language, and stored in a computer storage medium or data storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication.

The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a processor board, a server platform, or a motherboard, or (b) an end product.

The following examples pertain to further embodiments.

Example 1 may include a device comprising processing circuitry coupled to storage, the processing circuitry configured to: perform a functional test on a plurality of central processing unit (CPU) cells in a chain; propagate data through a combinatoric logic; capture results in sequential flip-flops associated with scan; utilize the results in a next combinatoric logic; and utilize shifted-out data to isolate a first broken cell based on the functional test.

Example 2 may include the device of example 1 and/or some other example herein, wherein the shifted-out data may be a scan dump.

Example 3 may include the device of example 1 and/or some other example herein, wherein the shifted-out data may be determined by shifting-out of sequential flip-flops data by serial flip-flops data.

Example 4 may include the device of example 3 and/or some other example herein, wherein the serial flip-flops are connected to the chain.

Example 5 may include the device of example 1 and/or some other example herein, wherein the processing circuitry may be further configured to hold execution of the functional test for a predetermined time period.

Example 6 may include the device of example 5 and/or some other example herein, wherein the predetermined time period may be a number of CPU cycles.

Example 7 may include the device of example 1 and/or some other example herein, wherein the processing circuitry may be further configured to resume the execution of the functional test after the data has been shifted-out.

Example 8 may include the device of example 1 and/or some other example herein, wherein the processing circuitry may be further configured to repeat holding the execution of the functional test and resuming the execution of the functional test until completion of the functional.

Example 9 may include the device of example 1 and/or some other example herein, wherein the shifted-out data may be accumulated data after the completion of the functional test.

Example 10 may include a non-transitory computer-readable medium storing computer-executable instructions which when executed by one or more processors result in performing operations comprising: performing a functional test on a plurality of central processing unit (CPU) cells in a chain; propagating data through a combinatoric logic; capturing results in sequential flip-flops associated with scan; utilizing the results in a next combinatoric logic; and utilizing shifted-out data to isolate a first broken cell based on the functional test.

Example 11 may include the non-transitory computer-readable medium of example 1 and/or some other example herein, wherein the shifted-out data may be a scan dump.

Example 12 may include the non-transitory computer-readable medium of example 1 and/or some other example herein, wherein the shifted-out data may be determined by shifting-out of sequential flip-flops data by serial flip-flops data.

Example 13 may include the non-transitory computer-readable medium of example 3 and/or some other example herein, wherein the serial flip-flops are connected to the chain.

Example 14 may include the non-transitory computer-readable medium of example 1 and/or some other example herein, wherein the operations further comprise hold execution of the functional test for a predetermined time period.

Example 15 may include the non-transitory computer-readable medium of example 5 and/or some other example herein, wherein the predetermined time period may be a number of CPU cycles.

Example 16 may include the non-transitory computer-readable medium of example 1 and/or some other example herein, wherein the operations further comprise resume the execution of the functional test after the data has been shifted-out.

Example 17 may include the non-transitory computer-readable medium of example 1 and/or some other example herein, wherein the operations further comprise repeat holding the execution of the functional test and resuming the execution of the functional test until completion of the functional.

Example 18 may include the non-transitory computer-readable medium of example 1 and/or some other example herein, wherein the shifted-out data may be accumulated data after the completion of the functional test.

Example 19 may include a method comprising: performing, by one or more processors, a functional test on a plurality of central processing unit (CPU) cells in a chain; propagating data through a combinatoric logic; capturing results in sequential flip-flops associated with scan; utilizing the results in a next combinatoric logic; and utilizing shifted-out data to isolate a first broken cell based on the functional test.

Example 20 may include the method of example 1 and/or some other example herein, wherein the shifted-out data may be a scan dump.

Example 21 may include the method of example 1 and/or some other example herein, wherein the shifted-out data may be determined by shifting-out of sequential flip-flops data by serial flip-flops data.

Example 22 may include the method of example 3 and/or some other example herein, wherein the serial flip-flops are connected to the chain.

Example 23 may include the method of example 1 and/or some other example herein, further comprising hold execution of the functional test for a predetermined time period.

Example 24 may include the method of example 5 and/or some other example herein, wherein the predetermined time period may be a number of CPU cycles.

Example 25 may include the method of example 1 and/or some other example herein, further comprising resume the execution of the functional test after the data has been shifted-out.

Example 26 may include the method of example 1 and/or some other example herein, further comprising repeat holding the execution of the functional test and resuming the execution of the functional test until completion of the functional.

Example 27 may include the method of example 1 and/or some other example herein, wherein the shifted-out data may be accumulated data after the completion of the functional test.

Example 28 may include an apparatus comprising means for: performing a functional test on a plurality of central processing unit (CPU) cells in a chain; propagating data through a combinatoric logic; capturing results in sequential flip-flops associated with scan; utilizing the results in a next combinatoric logic; and utilizing shifted-out data to isolate a first broken cell based on the functional test.

Example 29 may include the apparatus of example 1 and/or some other example herein, wherein the shifted-out data may be a scan dump.

Example 30 may include the apparatus of example 1 and/or some other example herein, wherein the shifted-out data may be determined by shifting-out of sequential flip-flops data by serial flip-flops data.

Example 31 may include the apparatus of example 3 and/or some other example herein, wherein the serial flip-flops are connected to the chain.

Example 32 may include the apparatus of example 1 and/or some other example herein, further comprising hold execution of the functional test for a predetermined time period.

Example 33 may include the apparatus of example 5 and/or some other example herein, wherein the predetermined time period may be a number of CPU cycles.

Example 34 may include the apparatus of example 1 and/or some other example herein, further comprising resume the execution of the functional test after the data has been shifted-out.

Example 35 may include the apparatus of example 1 and/or some other example herein, further comprising repeat holding the execution of the functional test and resuming the execution of the functional test until completion of the functional.

Example 36 may include the apparatus of example 1 and/or some other example herein, wherein the shifted-out data may be accumulated data after the completion of the functional test.

Embodiments according to the disclosure are in particular disclosed in the attached claims directed to a method, a storage medium, a device and a computer program product, wherein any feature mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Certain aspects of the disclosure are described above with reference to block and flow diagrams of systems, methods, apparatuses, and/or computer program products according to various implementations. It will be understood that one or more blocks of the block diagrams and flow diagrams, and combinations of blocks in the block diagrams and the flow diagrams, respectively, may be implemented by computer-executable program instructions. Likewise, some blocks of the block diagrams and flow diagrams may not necessarily need to be performed in the order presented, or may not necessarily need to be performed at all, according to some implementations.

These computer-executable program instructions may be loaded onto a special-purpose computer or other particular machine, a processor, or other programmable data processing apparatus to produce a particular machine, such that the instructions that execute on the computer, processor, or other programmable data processing apparatus create means for implementing one or more functions specified in the flow diagram block or blocks. These computer program instructions may also be stored in a computer-readable storage media or memory that may direct a computer or other programmable data processing apparatus to function in a particular manner, such that the instructions stored in the computer-readable storage media produce an article of manufacture including instruction means that implement one or more functions specified in the flow diagram block or blocks. As an example, certain implementations may provide for a computer program product, comprising a computer-readable storage medium having a computer-readable program code or program instructions implemented therein, said computer-readable program code adapted to be executed to implement one or more functions specified in the flow diagram block or blocks. The computer program instructions may also be loaded onto a computer or other programmable data processing apparatus to cause a series of operational elements or steps to be performed on the computer or other programmable apparatus to produce a computer-implemented process such that the instructions that execute on the computer or other programmable apparatus provide elements or steps for implementing the functions specified in the flow diagram block or blocks.

Accordingly, blocks of the block diagrams and flow diagrams support combinations of means for performing the specified functions, combinations of elements or steps for performing the specified functions and program instruction means for performing the specified functions. It will also be understood that each block of the block diagrams and flow diagrams, and combinations of blocks in the block diagrams and flow diagrams, may be implemented by special-purpose, hardware-based computer systems that perform the specified functions, elements or steps, or combinations of special-purpose hardware and computer instructions.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A device, the device comprising processing circuitry coupled to storage, the processing circuitry configured to:
perform a functional test on a plurality of central processing unit (CPU) cells in a chain;
propagate data through a combinatoric logic;
capture results in sequential flip-flops associated with scan;
utilize the results in a next combinatoric logic; and
utilize shifted-out data to isolate a first broken cell based on the functional test.

2. The device of claim 1, wherein the shifted-out data is a scan dump.

3. The device of claim 1, wherein the shifted-out data is determined by shifting-out of sequential flip-flops data by serial flip-flops data.

4. The device of claim 3, wherein the serial flip-flops are connected to the chain.

5. The device of claim 1, wherein the processing circuitry is further configured to hold execution of the functional test for a predetermined time period.

6. The device of claim 5, wherein the predetermined time period is a number of CPU cycles.

7. The device of claim 1, wherein the processing circuitry is further configured to resume the execution of the functional test after the data has been shifted-out.

8. The device of claim 1, wherein the processing circuitry is further configured to repeat holding the execution of the functional test and resuming the execution of the functional test until completion of the functional.

9. The device of claim 1, wherein the shifted-out data is accumulated data after the completion of the functional test.

10. A non-transitory computer-readable medium storing computer-executable instructions which when executed by one or more processors result in performing operations comprising:
performing a functional test on a plurality of central processing unit (CPU) cells in a chain;
propagating data through a combinatoric logic;
capturing results in sequential flip-flops associated with scan;
utilizing the results in a next combinatoric logic; and
utilizing shifted-out data to isolate a first broken cell based on the functional test.

11. The non-transitory computer-readable medium of claim 10, wherein the shifted-out data is a scan dump.

12. The non-transitory computer-readable medium of claim 10, wherein the shifted-out data is determined by shifting-out of sequential flip-flops data by serial flip-flops data.

13. The non-transitory computer-readable medium of claim 12, wherein the serial flip-flops are connected to the chain.

14. The non-transitory computer-readable medium of claim 10, wherein the operations further comprise hold execution of the functional test for a predetermined time period.

15. The non-transitory computer-readable medium of claim 14, wherein the predetermined time period is a number of CPU cycles.

16. The non-transitory computer-readable medium of claim 10, wherein the operations further comprise resume the execution of the functional test after the data has been shifted-out.

17. The non-transitory computer-readable medium of claim 10, wherein the operations further comprise repeat holding the execution of the functional test and resuming the execution of the functional test until completion of the functional.

18. The non-transitory computer-readable medium of claim 10, wherein the shifted-out data is accumulated data after the completion of the functional test.

19. A method comprising:
performing, by one or more processors, a functional test on a plurality of central processing unit (CPU) cells in a chain;
propagating data through a combinatoric logic;
capturing results in sequential flip-flops associated with scan;
utilizing the results in a next combinatoric logic; and
utilizing shifted-out data to isolate a first broken cell based on the functional test.

20. The method of claim 19, wherein the shifted-out data is a scan dump.
